(19) United States
(12) Patent Application Publication
(10) Pub. No.: US 2026/0136544 A1
(43) Pub. Date: May 14, 2026

(54) BARRIER IN THREE-DIMENSIONAL MEMORY CIRCUITS

(71) Applicant: Samsung Electronics Co., Ltd., Suwon-si, Gyeonggi-do (KR)

(72) Inventors: Huiwen XU, Cupertino, CA (US); Don Koun LEE, San Jose, CA (US); Adeniji ADETAYO, San Jose, CA (US)

(21) Appl. No.: 19/334,794

(22) Filed: Sep. 19, 2025

Related U.S. Application Data
(60) Provisional application No. 63/720,160, filed on Nov. 13, 2024.

(51) Int. Cl. H10B 12/00

(52) U.S. Cl. CPC H10B 12/488; H10B 12/02

(57) ABSTRACT

A system and a method for a barrier region are disclosed. The barrier region includes a barrier structure, a first strip, and a second strip. The barrier structure includes a protecting liner surrounding a material configured to protect a wordline (WL) area from a process effect. The first strip extends longitudinally in a first direction and is separated into a first segment and a second segment by a space. The second strip extends longitudinally in a second direction and intersects the second segment. The barrier structure extends longitudinally in the second direction between the first segment and the second segment in the space. The barrier structure is positioned between the WL area and one of a WL dummy area or a cell array area of a memory circuit.

### CROSS-REFERENCE TO RELATED APPLICATION

This application claims the priority benefit under 35 U.S.C. § 119(e) of U.S. Provisional Patent Application Ser. No. 63/720,160 filed on Nov. 13, 2024, the disclosure of which is incorporated by reference in its entirety as if fully set forth herein.

### TECHNICAL FIELD

The disclosure generally relates to memory devices. More particularly, the subject matter disclosed herein relates to barrier in three-dimensional (3D) memory circuits.

### BACKGROUND

The present background section is intended to provide context only, and the disclosure of any concept in this section does not constitute an admission that said concept is prior art.

Three-dimensional (3D) memory configurations have been increasingly popular. 3D memory devices, such as vertically stacked dynamic random-access memory (VSDRAM) and vertical NAND (V-NAND) flash memory, include memory cells that are stacked vertically to increase storage density. One feature of 3D memory circuits is the arrangement of the bit lines (BLs) and wordlines (WLs). As the memory density increases, the arrangement of BLs and WLs may cause issues such as shorts which refer to the defective electrical connections between two points. In addition, the arrangement of the WL pad area may be affected by etching chemicals from the WL etching and recessing processes.

Existing techniques for preventing shorts and other device failures, however, face several challenges, especially for high density and high aspect ratio memory circuits. Techniques such as two WL photolithography steps, precise device profile fabrication, optimized patterning and lithography, precise deposition of insulating materials, and analysis of device profiles are costly, difficult to implement, and may still have risks of shorts and defects.

The above information disclosed in this Background section is only for enhancement of understanding of the background of the disclosure and therefore it may contain information that does not constitute prior art.

### SUMMARY

To overcome these issues, systems and methods are described herein for a technique of forming a barrier region in a three-dimensional (3D) memory device. In some embodiments, the barrier region includes a barrier structure, a first strip, and a second strip. The barrier structure includes a protecting liner surrounding a material configured to protect a WL area from a process effect. The first strip extends longitudinally in a first direction and is separated into a first segment and a second segment by a space. The second strip extends longitudinally in a second direction and intersects the second segment. The barrier structure extends longitudinally in the second direction between the first segment and the second segment in the space. The barrier structure is positioned between the WL area and one of a WL dummy area or a cell array area of a memory circuit. In some embodiments, the protecting liner is a silicon nitride liner and the material is amorphous carbon (aC). In some embodiments, the first strip is aligned with a WL trench and the second strip is aligned with a deep trench isolation (DTI) trench. In some embodiments, the WL area is a WL pad area.

In some embodiments, a process of forming of the barrier region includes embedding a barrier structure in a three-dimensional (3D) structure of the memory circuit, creating an isolation trench pattern having gap-filled amorphous carbon (aC) in the 3D structure, forming a wordline (WL) trench in the 3D structure, ashing the gap-filled aC from the WL trench, preparing for metal deposition in one or more pathways for the memory circuit, depositing metal in the one or more WL pathways, and eliminating one or more tier-to-tier shorts formed at corresponding one or more WL ends.

### BRIEF DESCRIPTION OF THE DRAWINGS

In the following section, the aspects of the subject matter disclosed herein will be described with reference to exemplary embodiments illustrated in the figures, in which:

FIG. 1 is a block diagram illustrating a system that utilizes a 3D memory circuit according to an embodiment.

FIG. 2 is a diagram illustrating a 3D memory circuit that utilizes a barrier region according to an embodiment.

FIG. 3 is a diagram illustrating a first layout of the barrier region according to an embodiment.

FIG. 4 is a diagram illustrating a second layout of the barrier region according to an embodiment.

FIG. 5 is a diagram illustrating an overall integration process according to an embodiment.

FIG. 6 is a diagram illustrating an ISO process according to an embodiment.

FIG. 7 is a diagram illustrating a WL process according to an embodiment.

FIG. 8 is a diagram illustrating a first part of the WL process according to an embodiment.

FIG. 9 is a diagram illustrating a second part of the WL process according to an embodiment.

FIG. 10 is a diagram illustrating a process of tier-to-tier short cutting according to an embodiment.

FIG. 11 is a flow chart illustrating a process of forming the barrier structure for a memory circuit according to an embodiment.

FIG. 12 is a flow chart illustrating the process of preparing for metal deposition according to an embodiment.

FIG. 13 is a flow chart illustrating the process of eliminating tier-to-tier shorts according to an embodiment.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements. In the following, figures depicting various components, structures, interconnections, configurations, and steps of fabrication, are mainly for illustrative purposes. They are not intended to describe these elements accurately. A cross-sectional representation may be used to refer to a 3D block in a 3D structure. In some cases, relevant parts in a figure are shown clearly while other parts are shown with less sharpness or clarity to avoid confusion and improve contrast and clarity. These parts may be referenced in earlier figures and therefore do not need to be described again. These parts may also have little relationship with the part(s) being described. In addition, the shading of the parts in the figures may not have a consistent design and may be changed to maintain clarity and contrast in the figures. For example, part A may have a light shading in Fig. X but may be heavily shaded in Fig. Y. Moreover, as mentioned above, components in a figure may not be drawn with proper scales.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

The term “monolithic,” as used herein, refers to “formed of a single element.” The single, or one-body, element may include a uniformly distributed material. A “monolithic formation” is a formation of elements at the same time to create a monolithic, single, or one-body element. This contrasts with formation of an element by stitching two or more separate elements together, or integrating two or more separate elements together by joining them or connecting them together. Stitching two or more separate elements together may create uneven surfaces at the stitching site such that the surfaces become skew, crooked, or warped which may lead to tier-to-tier shorts, breaks, and other defects.

The term “pathway,” as used here in, refers to the patterned channel or trench that is prepared to be filled with material according to the designated function. When it is filled with metal, it becomes a conducting line used as a WL or BL in a memory circuit or any other conducting lines that carry signals in a circuit. The term “pathway” is sometimes used to mean a channel, a hollow space, a trench, a pattern, a patterned line, or a line.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Many applications, especially applications in Artificial Intelligence (AI) and signal processing, require a vast storage capacity and high throughput computations. To satisfy these needs, highly dense memory circuits in 3D are developed. A typical 3D dynamic random-access memory (DRAM) device may stack multiple layers of memory cells vertically. Bitlines (BLs) and wordlines (WLs) may be arranged vertically to access cells in different layers. BLs and WLs are conductive elements that are used to select memory cells which may be arranged in a row-and-column array. A WL pad is a structure that allows connecting the WLs to other parts of the memory circuit and external circuits. A WL may therefore run from the pad area to the array area.

In the following, systems and methods are described for a technique of forming a barrier region in a three-dimensional (3D) memory device. In some embodiments, the barrier region includes a barrier structure, a first strip, and a second strip. The barrier structure acts as a dam or a blocker to block the etching. The barrier structure includes a protecting or barrier liner surrounding a material configured to protect a WL area from a process effect. The first strip extends longitudinally in a first direction and is separated into a first segment and a second segment by a space. The second strip extends longitudinally in a second direction and intersects the second segment. The barrier structure extends longitudinally in the second direction between the first segment and the second segment in the space. The barrier structure is positioned between the WL area and one of a WL dummy area or a cell array area of a memory circuit. In some embodiments, the protecting liner is a silicon nitride liner and the material is amorphous carbon (aC). In some embodiments, the first strip is aligned with a word line (WL) trench and the second strip is aligned with a deep trench isolation (DTI) trench. In some embodiments, the WL area is a WL pad area.

In some embodiments, a process of forming of the barrier region includes embedding a barrier structure in a three-dimensional (3D) structure of the memory circuit, creating an isolation trench pattern having gap-filled amorphous carbon (aC) in the 3D structure, forming a wordline (WL) trench in the 3D structure, ashing the gap-filled aC from the WL trench, preparing for metal deposition in one or more pathways for the memory circuit, depositing metal in the one or more WL pathways, and eliminating one or more tier-to-tier shorts formed at corresponding one or more WL ends.

The barrier structure provides at least three advantages as follows:

First, the barrier structure enables the aC gap filling during an etching process. The barrier liner protects the aC in the barrier (for later use) while allowing the aC in the WL trench to be removed for etching. It acts as an etch stop to stop the etching to go beyond its position. Using aC for etching provides precise control with good alignment. The profile of the etching using aC is clean or flat. There will be no tapering profile. No High Aspect Ratio Etching (HARE) mechanism is involved.

Second, the barrier structure protects the WL pad area from numerous effects of etching, recessing, and lateral recesses in the WL trench. The etchings and recesses in the WL trench can therefore be performed safely without concerns about impacting the WL pad area. This will help in the formation of monolithic or one-body WLs where the surface of the WLs at the boundary between the WL pad area and the cell array area is flat or even, without skewing due to stitching.

Third, the aC in the barrier structure may be used to eliminate tier-to-tier shorts caused by interconnections at the ends of the WLs. This will result in WL tiers operating independently.

In addition, the process is efficient, requires fewer steps than the conventional techniques, uses only one WL photolithography step instead of two in the conventional techniques, and gains space area. The barrier structure is self-formed through the formation of the trenches and the liner and the gap filling of sacrificial material. The barrier structure also helps in constructing a one-body or monolithic WL.

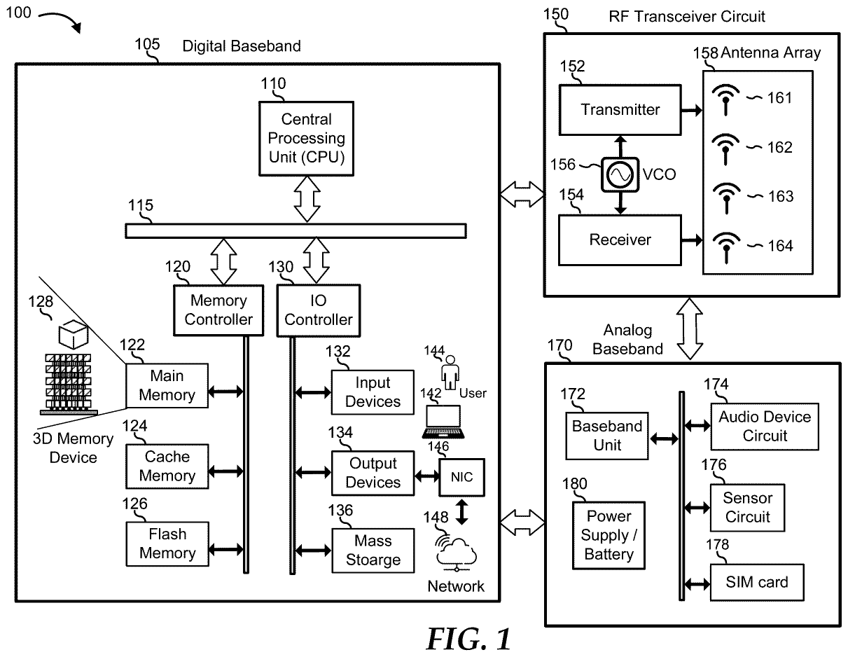

FIG. 1 is a block diagram illustrating a system that utilizes a 3D memory circuit according to an embodiment. The system 100 includes a digital baseband circuit 105, a radio frequency (RF) transceiver circuit 150, and an analog baseband circuit 170. The system 100 may represent a digital system or a mobile system. When the system 100 is used as a digital system without mobile circuitry, the RF transceiver circuit 160, and the analog baseband circuit 190 are not used. In addition, when the system 100 is used as a mobile device, many of the digital devices are scaled back and some devices may not be available.

The digital baseband circuit 105 includes central processing unit (CPU) 110, a memory controller 120, and an IO controller 130. The system 100 may include more or less than the above components. In addition, a component may be integrated into another component. The integration may be partial and/or overlapped. For example, the memory controller 120 and the I/O controller 130 may be integrated into one single controller.

The CPU 110 is a programmable device that may execute a program or a collection of instructions to carry out a task. It may be a host that controls or manages other processors or devices. In particular, the CPU 110 may include applications programming interfaces (APIs), applications, or drivers that are executed by the CPU 110 to perform specified tasks. The CPU 110 may be a general-purpose processor, a digital signal processor, a microcontroller, or a specially designed processor. It may include a single core or multiple cores. Each core may have multi-way multi-threading. The CPU 110 may have simultaneous multithreading feature to further exploit the parallelism due to multiple threads across the multiple cores. In addition, the CPU 110 may have internal caches at multiple levels. The CPU 110 communicates with other devices in the system via a bus 115. The bus 115 may be any suitable bus connecting the CPU 110 to other devices. For example, the bus 115 may be a Direct Media Interface (DMI). The bus 115 may also include other custom buses such as bus for the interface to the analog section when the system 100 is used as a mobile device.

The memory controller 120 controls memory devices such as a main memory 122, a cache memory 124, and a flash memory 126. The main memory 122 includes random access memory (RAM) including static RAM (SRAM) and dynamic RAM (DRAM) and/or the read-only memory (ROM) and other types of memory. The DRAM may include Synchronous DRAM (SDRAM), Double Data Rate SDRAM (DDR SDRAM) with variations (e.g., DDR2, DDR3, DDR4, DDR5, and DDR6). The main memory 122 may store instructions or programs, loaded from a mass storage device, that, when executed by the CPU 110, cause the CPU 110 to perform operations for a specified task. It may also store data used in the operations. The ROM may be a solid-state drive (SSD) and include instructions, programs, constants, or data that are maintained whether it is powered or not. The instructions or programs may correspond to the functionalities described in the following. In one embodiment, the main memory 122 includes a 3D memory device or circuit 128 such as VSDRAM and V-NAND flash memory, or any other memory devices that have memory cells that are stacked vertically to increase storage density

The I/O controller 130 controls input devices 132, output devices 134, and mass storage 136. The input devices 132 may include a keyboard, a mouse, an image sensor or camera, a game console, and a microphone. Other input devices may also be available such as stylus, joystick, scanner, and light pen. The input devices may also have a user interface to interface to a computer or laptop 142 and/or a user 144. The output devices 134 may include a printer, a monitor or screen, a headset, and a multi-monitor set. When used as a computing device without mobile features, the monitor is a high-resolution display. For games and other multi-display mode, the multi-monitor set provides high-resolution with multiple monitors (e.g., three monitors). When used for mobile communication, the screen provides the primary interface for the user to navigate, access various applications and perform tasks. The screen may use organic light-emitting diode (OLED) (super retina) display with multi-touch or haptic touch feature. The mass storage 136 may include CD-ROM, hard disk, and solid-state drives (SSDs). The I/O controller 130 also has a network interface card (NIC) 145 which provides an interface to a network and wireless medium 148.

Additional devices or bus interfaces may be available for interconnections and/or expansion. Some examples may include the Peripheral Component Interconnect Express (PCIe) bus, the Universal Serial Bus (USB), etc.

The RF transceiver circuit 150 includes a transmitter 152, an antenna array 158, a voltage-controlled oscillator (VCO) 156, and a receiver 154. The RF circuit 150 operates at a high GHz frequency band to accommodate modern cellular equipment such as the wireless fifth generation (5G).

The transmitter 152 transmits the digital baseband data to the antenna array 158. The transmitter 152 may include a digital-to-analog converter (DAC), an automatic gain controller (AGC), an intermediate frequency (IF) circuit, a mixer, an RF circuit, and a power amplifier (PA). Other components may include filters, amplifiers, multiplexers, coaxial cables, phase shifters, etc. The DAC converts digital data f₁ into an analog signal f₂. The AGC automatically adjusts the signal amplitude of f₂ to generate a signal f₃ to maintain a consistent strength level in a dynamic and changing environment. The IF circuit performs intermediate frequency processes such as filtering to generate a signal f₄. The mixer converts the frequency of the signal f₄ to another frequency. This is done by mixing the signal f₄ with a signal vₜ from the VCO 156. Mixing here refers to frequency modulation which translates the signal f₄ to a signal f₅ at a different frequency. For transmitter, the translated frequency is higher than the frequency of f₄. The conversion is called up-conversion. For 5G communication, the frequency range may include low-band (below 1 GHz), mid-band (1 GHz to 6 GHz), and high-band (24 GHz to 53 GHz or higher). The resulting signal f₅ then goes through various radio frequency processes performed by the RF circuit such as high-pass filtering to produce a signal f₆. The signal f₆ is strengthened and amplified by the PA to produce a signal f₇. The signal f₇ then goes to the antenna array 158 to be transmitted to an appropriate destination and medium (e.g., base station). The antenna array 158 uses beam forming to focus radio waves from f₇ in a desired direction. The antenna array 158 may be used for both transmitting and receiving. On receiving, the antenna array 158 receives an RF signal and sends it to the receiver 154. The number of antennas in the antenna array 158 depends on the desired coverage. The antenna array 158 may include antennas 161, 162, 163, and 164 configured to operate with 5G communication, Gigabit Long Term Evolution (LTE), Wi-Fi (e.g., 2.4 GHz, 5 GHz, and 6Ghz), and Bluetooth, respectively. The number of antennas may be more or less than the above.

The VCO 156 couples multiple in-phase oscillators together to provide low phase noise oscillation. It generates signals vₜ and vᵣ to the mixers at specified frequencies. It may include multiple oscillation core circuits (or VCO cores) to provide high-frequency periodic signals.

The receiver 154 processes the received signal r₇ in a manner reverse from the transmitter 152. It may include a low noise amplifier (LNA), an RF circuit, a mixer, an IF circuit, an AGC, and an analog-to-digital converter (ADC). The receiver 154 may include more or less than the above components. The LNA amplifies the weak signal r₇ while maintaining a good signal-to-noise ratio (SNR) to produce a signal r₆ for further processing. The signal r₆ is next processed by the RF circuit such as band-pass filtering to provide a signal r₅. Additional filtering may be performed in the next stages. The signal r₅ is then mixed with the signal vᵣ from the VCO 156 to down convert the signal r₅ to a signal r₄ at an appropriate low frequency. Like the mixer in the transmitter 152 but with a reverse operation, the mixer in the receiver performs frequency modulation to translate the high frequency signal r₅ to a low frequency signal r₄. The signal r₄ goes through IF processing such as additional filtering by the IF circuit to produce a signal r₃. The AGC amplifies and strengthens the signal and generates a signal r₂. The ADC converts the analog signal r₂ into digital data r₁ which will be processed by the CPU 110.

The analog baseband circuit 170 provides analog processing for various components. It handles processing of signals and data between the digital baseband circuit and the RF transceiver circuit 150. It may include analog and digital components to perform various tasks including modulation/demodulation, controlling the RF transceiver circuit 150, special circuitry for 3G, 4G/LTE, Bluetooth, and 5G communication. It may also interface with an audio device circuit 174, a sensor circuit 176, a Subscriber Identity Module (SIM) card 178, and other components. The audio device circuit 174 may include operational blocks to process audio signals and perform audio-related functions such as filtering, correlation, speech recognition. It may include digital circuits to perform Fast Fourier Transform (FFT) to perform signal processing in the frequency domain. The sensor circuit 176 may include a variety of sensors such as proximity, ambient light, motion (accelerometer and gyroscope, compass, barometer, fingerprint sensor for touch identification (ID), image sensors for face ID, light detection and ranging (LiDAR) scanner, etc. The SIM card 178 is a small, removable chip that stores the user's phone number and carrier information, allowing the device to connect to a cellular network.

The power supply and battery circuit 180 provides power and battery backup supply to the entire system. It may include a charger to charge the battery. The battery may be a rechargeable battery, of Lithium-Ion battery. Power management may be performed by application software and circuits to provide low power mode and performance management.

The system 100 is an example that illustrates the role of 3D memory devices in a laptop, desktop or mobile environment. In many cases, the environment of the applications adds additional requirements including low power consumption, reliable signal integrity, fault-tolerance, and reliable operations in extreme conditions including heat and tight space. Examples of other applications that would benefit from 3D memory devices or circuits include mobile communication (e.g., smart phones, base stations, user equipment), cameras, vehicles, entertainment (e.g., games, multimedia, music, movies), technical designs (e.g., animation, graphics), medical (e.g., visualization, medical imaging), robotics, drones, automatic test equipment, audio processing, speech synthesizer, video and image analysis, vision, automatic face recognition, artificial intelligence (AI) applications, and data centers.

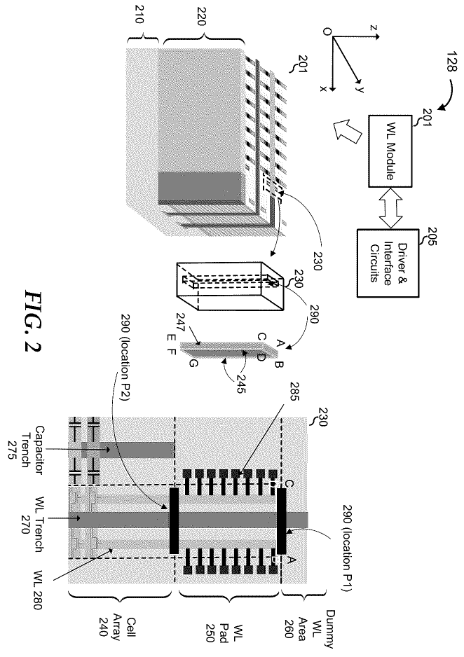

FIG. 2 is a diagram illustrating a 3D memory circuit 128 that utilizes a barrier region according to an embodiment. The 3D memory circuit 128 includes a WL module 201, driver and interface circuits 205, and other circuit elements (not shown). The WL module 201 is a 3D structure. It includes a substrate 210 and a circuit structure 220. The substrate 210 is the foundation for the circuit structure 220. The circuit structure 220 includes circuit components and interconnections that form the memory circuit. The circuit components may include transistors, capacitors, resistors, and other elements. These elements may form functional circuits such as decoders, drivers, and buffers. The interconnections may include various connecting lines, BLs, and WLs. The circuit structure 220 includes a barrier region 230 and other regions, The barrier region 230 is a 3D structure occupying a portion from top to bottom of the circuit structure 220. FIG. 2 shows the 3D structure and the cross section as seen from the top. The circuit structure 220 includes three areas or regions: a cell array 2 area 40, a WL pad area 250, and a dummy WL area 260. The barrier region 230 includes a WL trench 270, a capacitor trench 275, a number of WLs 280, and a barrier structure 290.

The cell array area 240 includes array of memory cells. In some embodiments, the memory cells include capacitors and transistors for access switching. The WL pad area 250 includes contacts for interconnections to various circuits and components such as row and column decoders, switching circuits. It may include a number of contact pads 285 for interconnections. The dummy WL area 260 includes a number of dummy WLs that are not used for functioning as WLs. Instead, the dummy WLs help in the control the electrical characteristics of functional WLs such as electrical shields, noise control, timing control, etc.

The WL trench 270 is a trench that is configured for forming WLs and interconnections to other components. The capacitor trench 275 is a trench that is configured for forming capacitors and other components. The WL trench 270 and the capacitor trench 275 extending longitudinal in the same direction.

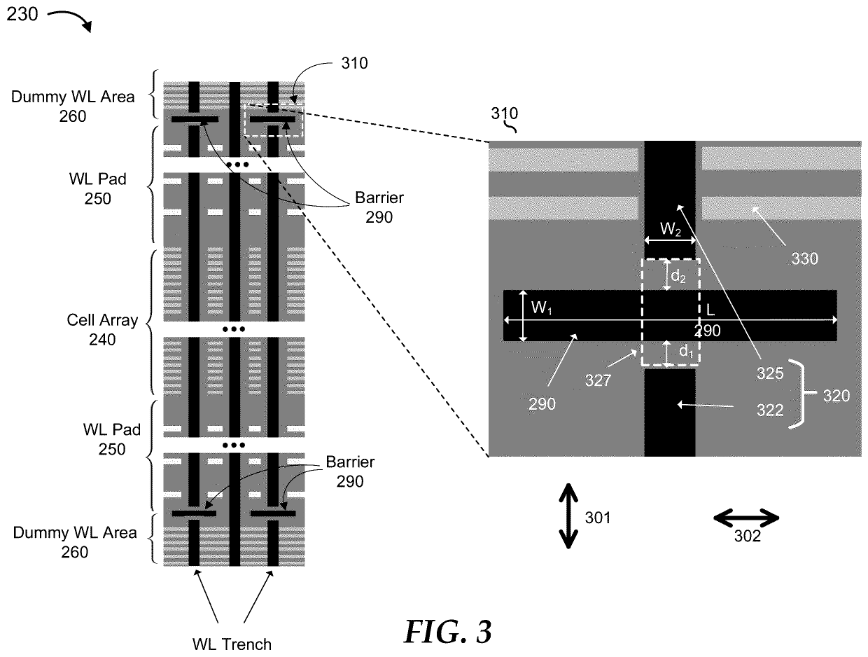

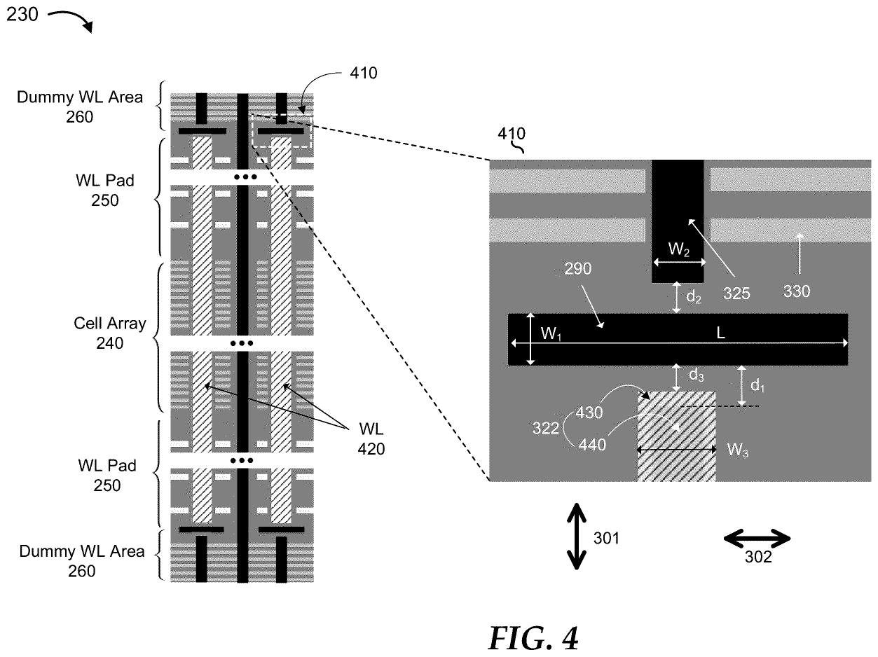

The barrier structure 290 provides the barrier function. It is a 3D structure defined by the vertices, A, B, C, D, E, F, G, and H (not shown). The vertices A, B, C, and D are visible from the top and define a rectangle. The barrier structure 290 may include two types of material. One is used as a liner and one is used as a sacrificial material. The liner acts as an etch stop and the sacrificial material may be used for cutting metal process in the step to remove tier-to-tier shorts. In one embodiment, the sacrificial material is aC. The sacrificial material may be surrounded by a barrier liner 245. In some embodiments, the barrier liner 245 includes silicon nitride. The barrier liner 245 protects the internal material 247. Initially, the internal material 247 may include an oxide. During the trench process, the oxide may be removed and replaced by aC. The aC in the barrier structure is referred to as barrier aC to distinguish from the aC in the WL trench, referred to as trench aC. The liner 245 protects the barrier aC from being removed or exhumed when the trench aC is removed or exhumed during the etching process of the WL trench. The barrier aC is then used near the end of the WL integration process to eliminate the tier-to-tier shorts at the interconnections at the ends of the WLs. The barrier structure 290 may be placed in at least two locations: location P1 at a boundary site between the WL pad area 250 and the dummy WL area 260 and location P2 at a boundary site between the WL pad area 250 and the cell array area 240. The barrier structure 290 may be placed at one boundary site or at both boundary sites. In some embodiments, the barrier structure 290 may be placed across the WL trench 270, across the capacitor trench 275, or both the WL trench 270, and the capacitor trench 275. Other sites that may need the protection or etch stop feature of the barrier structure 290 may also be appropriate. The geometry of the barrier structure in relation to the WLs and other lateral lines will be described in FIG. 3 and FIG. 4.

FIG. 3 is a diagram illustrating a first layout of the barrier region 230 according to an embodiment. The barrier region 230 includes the cell array 240, the WL pad area 250, and the dummy WL area 260, and the barrier structure 290. The barrier structure 290 are shown to be placed at two boundary sites. The cross section 310 shows the layout of the barrier structure 290 as seen from the top.

The barrier structure 290 is placed crossing a strip 320 which corresponds to the WL trench 270. The first strip 320 extends longitudinally in a first direction 301 and separated into a first segment 322 and a second segment 325 by a space 327. In one embodiment, the first strip is aligned with the WL trench 270. The second segment 325 intersects a second strip 330. The second strip 330 extends longitudinally in a second direction 302 and intersects the second segment 325. In some embodiments, the first direction 301 is substantially perpendicular to the second direction 302. In one embodiment, the second strip 330 is aligned with a lateral line which may be patterned in a deep trench isolation (DTI) trench. The barrier structure 290 extends longitudinally in the second direction 302 between the first segment 322 and the second segment 325 in the space 327. In addition, the barrier structure 290 is positioned between the first area and a second area of a memory circuit. In one embodiment, the first area is the WL pad area 250 and the second area is one of the WL dummy area 260 or the cell array area 240.

The barrier structure 290 may be positioned relative to the first segment 322 and the second segment 325 based on a predefined geometrical relationship. The barrier structure 290 may be positioned at a first distance d₁ from end of the first segment 322 and a second distance d₂ from end of the second segment 325. In some embodiments, d₂>d₁. The barrier structure 290 has a width W₁ and a length L. The first strip 320 has a width W₂. The width W₁ may be selected relative to W₂ to provide sufficient protection. In one embodiment, W₁ is approximately equal to W₂. In another embodiment W₁≠W_{2.} In some embodiments, a ratio between the width W₁ and the length L of the barrier is less than a predetermined value.

FIG. 4 is a diagram illustrating a second layout of the barrier region 230 according to an embodiment. The second layout in FIG. 4 is similar to that in FIG. 3 except that the WL trench 270 between the two barrier structures has a WL 420. Accordingly, for brevity, the description of the same components is omitted.

The cross section 410 of the region 230 is similar to the cross section 310 in FIG. 3 except that the strip 322 now includes a inner part 440 and an outer part 430. The outer part 430 may correspond to an extra layer of the WL. The distance between the barrier structure 290 and the first segment 322 is d₃, which may be shorter than d₁.

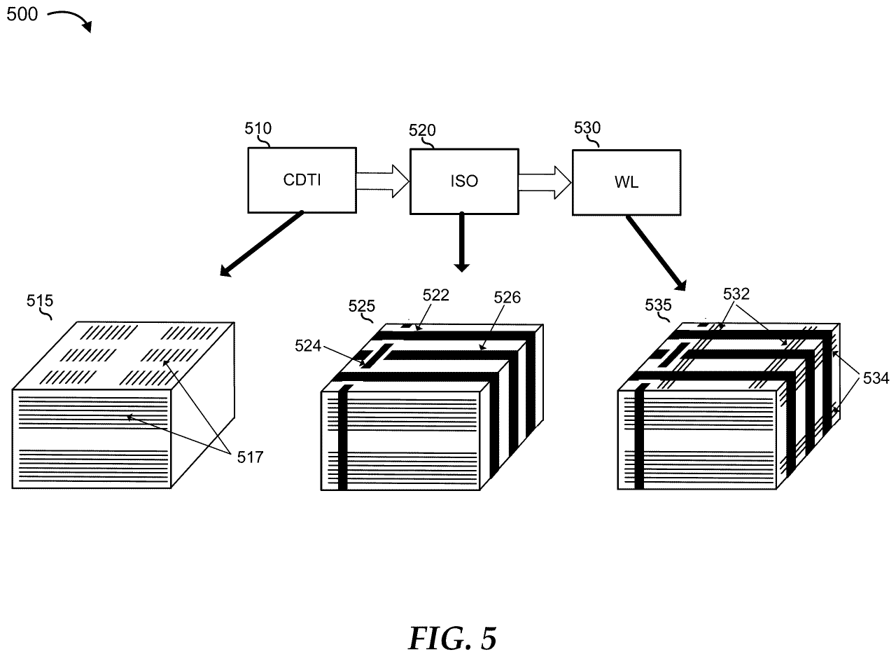

FIG. 5 is a diagram illustrating an overall integration process 500 according to an embodiment. The process 500 includes a cell/capacitor deep trench isolation (CDTI) process 510, an isolation (ISO), and a WL process 530. The integration process 500 may include more or less than the above processes or steps.

The CDTI process 510 creates patterns or trenches for cells or capacitors. It results in a structure 515. The structure 515 has the pattern 517 that corresponds to lines that are lateral to WLs. In one embodiment, the barrier structure 290 may be formed in this process.

The ISO process 520 creates patterns that will be used to form components and interconnections. It results in a structure 525. The structure 525 may include a capacitor trench 522, a WL trench 526, and a barrier pattern 524. The barrier pattern 524 corresponds to a site where the barrier structure 290 is located.

The WL process 530 creates various etches, recesses, and metallization to form transistors and capacitors and interconnections including lines 532 and 534. The lines 532 and 534 may become WLs and/or WL pad in the memory circuits.

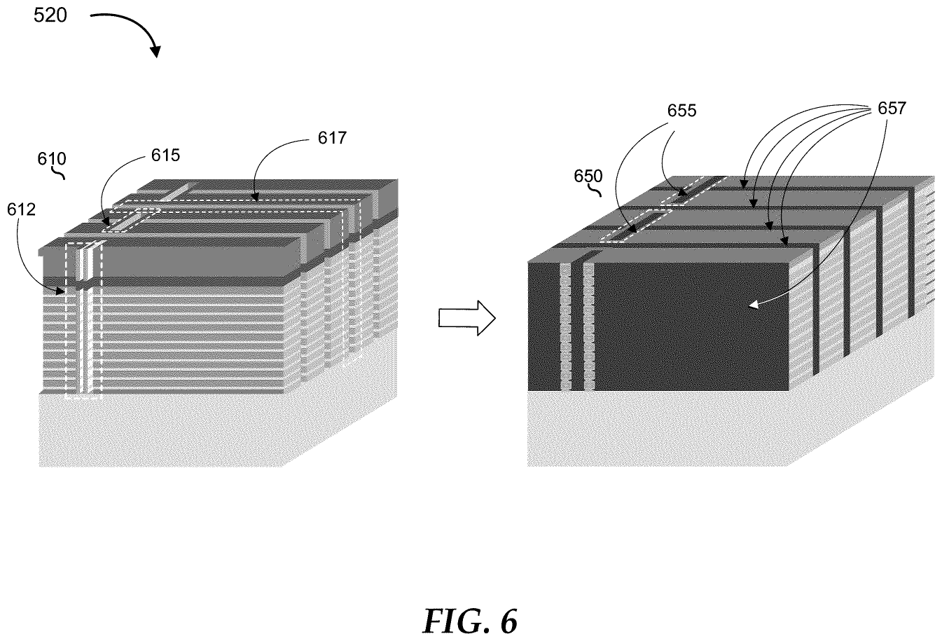

FIG. 6 is a diagram illustrating the ISO process 520 according to an embodiment. The ISO process 520 results in a structure 610 and a structure 650. The ISO process 520 may results in more or less than the above structures. For brevity, only two structures 610 and 650 are shown.

The structure 610 may correspond to an etching process. The etching results in patterns 612, 615, and 617. The pattern 612 may correspond to the barrier liner 245 (shown in FIG. 2) and location of the barrier structure 290. The pattern 615 may correspond to the barrier structure 290. The pattern 617 may correspond to the WL trench 270.

The structure 650 may correspond to various processes or steps including removing silicon-germanium, thinning silicon, gap filling of lateral oxide, forming silicon nitride liner, and gap filling aC. The trenches 655 and 657 are filled with aC. The trench 655 corresponds to barrier structures 290.

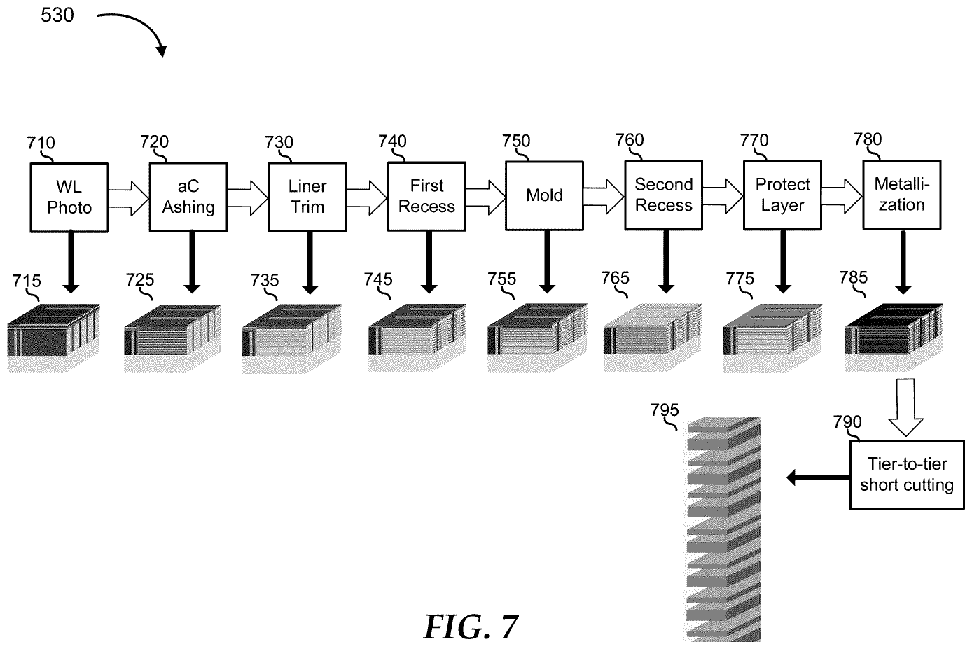

FIG. 7 is a diagram illustrating the WL process 530 according to an embodiment. The WL process 530 includes a WL photolithography 710, an aC ashing 720, a liner trim 730, a first recess 740, a mold 750, a second recess 760, a protect layer 770, a metallization 780, and a tier-to-tier short cutting 790. The WL process 530 may include more or less than the above processes or steps.

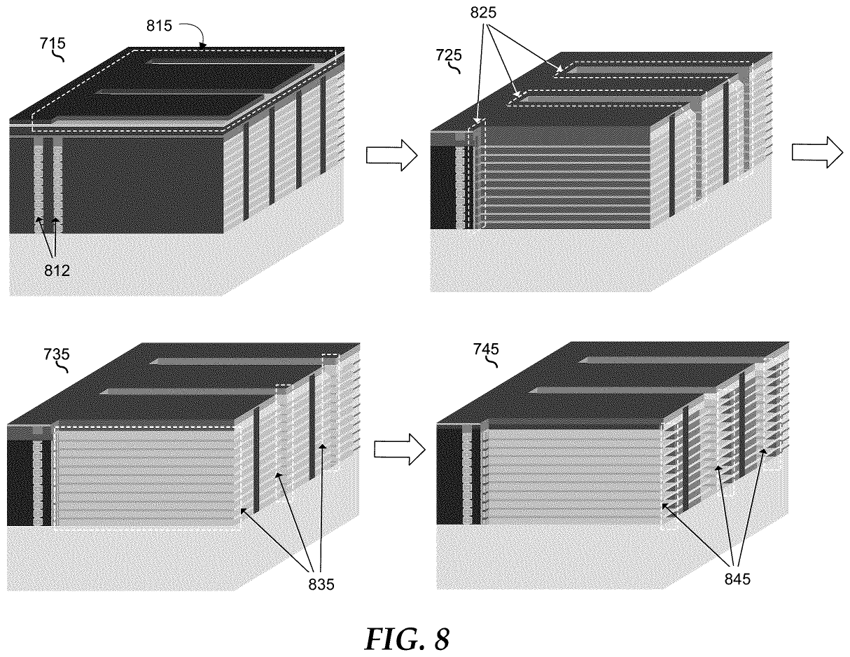

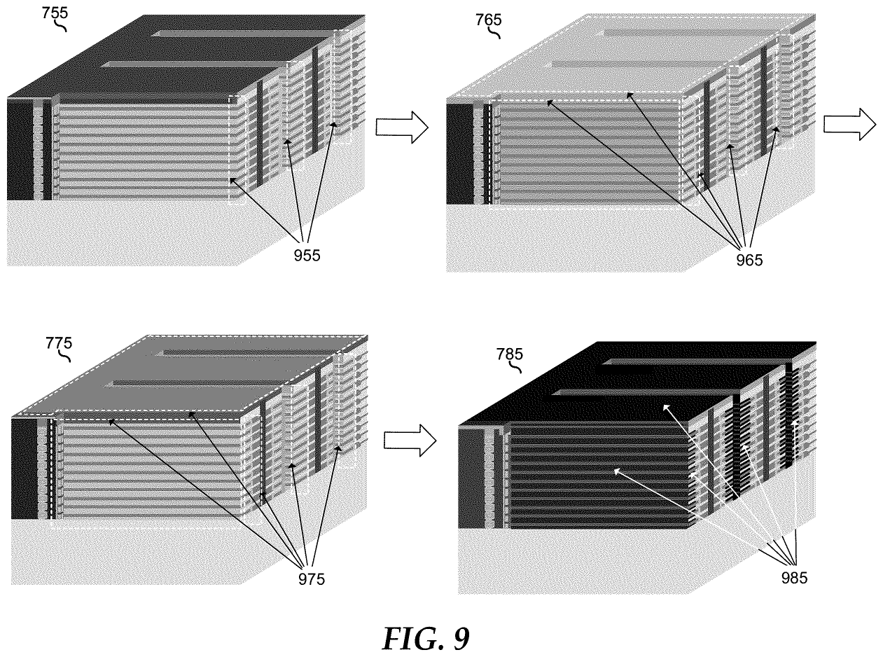

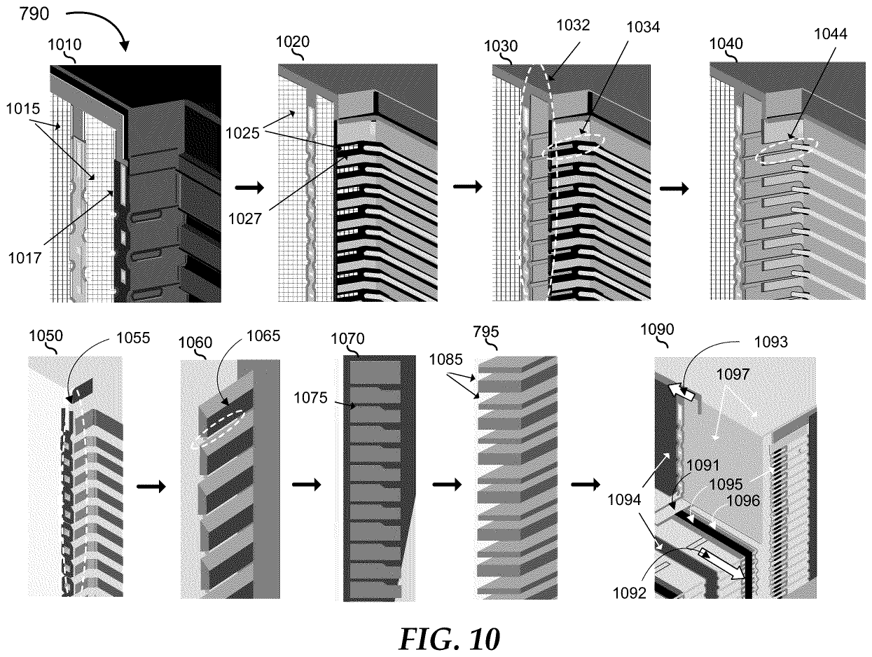

The WL photolithography 710, the aC ashing 720, the liner trim 730, the first recess 740, the mold 750, the second recess 760, the protect layer 770, the metallization 780, and the tier-to-tier short cutting 790 results in structures 715, 725, 735, 745, 755, 765, 775, 785, and 795, respectively. The structures 715, 725, 735, and 745 in the first part of the WL process 530 will be described in FIG. 8. The structures 755, 765, 775, and 785 in the second part of the WL process 530 will be described in FIG. 9. The structure 795 in the last part of the WL process 530 will be described in FIG. 10.

FIG. 8 is a diagram illustrating a first part of the WL process 530 shown in FIG. 7 according to an embodiment. The first part includes structures 715, 725, 735, and 745.

The structure 715 corresponds to a WL photolithography process. The photolithography process may be performed using any suitable technique including applying photoresist, exposing to ultraviolet light, dissolving the photoresist, etching, and stripping. The photomask contains the precise WL circuit pattern. In this process, the aC is gap filled in the trenches,

The structure 725 corresponds to an aC ashing process. aC is removed from the trenches 825, leaving barrier aC in the barrier structure. The structure 735 corresponds to liner trimming at the WL trenches 835. In one embodiment, the liner is silicon nitride. It acts as a stop etch. The structure 745 corresponds to a first recess at trenches 845. In one embodiment, the recess is a silicon oxide recess.

FIG. 9 is a diagram illustrating a second part of the WL process 530 shown in FIG. 7 according to an embodiment. The second part includes structures 755, 765, 775, and 785.

The structure 755 corresponds to a molding process at the WL trenches 955. In one embodiment, the molding involves at least an oxide mold or a nitride mold. In some embodiments, the molding includes a tri-layer mold of oxide, nitride, and oxide molds. The structure 765 corresponds to a second recess at the trenches and area 965. In one embodiment, the second recess is a nitride recess. The structure 775 corresponds to a protection layer process at the trenches and area 975. In one embodiment, the protection layer includes gate oxide. The structure 985 corresponds to a metallization process at the trenches and areas 985. The metallization includes depositing metal in pathways for WLs and other interconnections. In some embodiments, the metal may be any one of the following: tungsten (W), titanium nitride (TiN), molybdenum (Mo), aluminum (Al), copper (Cu), Cobalt (Co). ruthenium (Ru), iridium (Ir), platinum (Pt), tantalum (Ta), or rhodium (Rh). It may also be a combination of two or more of the above materials.

Due to the nature of metallization, metal may be smeared or spread in a form of semi-spherical shape at the end of the WL such that these shapes are connected together. Accordingly, a short may result through a vertical metal connection at the ends of the WLs. This vertical connection causes a tier-to-tier short that needs to be eliminated to provide WLs independent operations.

FIG. 10 is a diagram illustrating a process 790 of tier-to-tier short cutting according to an embodiment. The process 790 results in structures 1010, 1020, 1030, and 1040. Structures 1050, 1060, 1070 and 795 are expanded view of parts of the structures 1010, 1020, 1030, and 1040. The final result is a structure 1090.

The structure 1010 includes the aC layer 1015 of the barrier structure and a vertical metal connection 1017. As shown in structure 1050, the vertical connection in the area 1055 results in a tier-to-tier short. The structure 1020 and 1060 correspond to a first metal cut process. The first metal cut process creates small holes or openings 1027 or 1065. The structure 1030 exhumes or removes the aC in the barrier structure, showing the vertical connection 1032 and the metal residues 1034. After the aC is exhumed, the metal shorts are revealed or exposed as shown in the structure 1070 with the connections 1075. The structure 1040 correspond to a second metal cut at the area 1044 where metal has been removed. The structure 795 shows the metal parts are removed at the gaps 1085.

The structure 1090 shows the end of the WL process 530. An arrow 1092 points to the WL pad and cell array areas. The arrow 1093 points to the dummy WL area. The barrier structure 1091 is placed at the metal WL 1095 and the silicon nitride 1096. The aC is at the locations 1094.

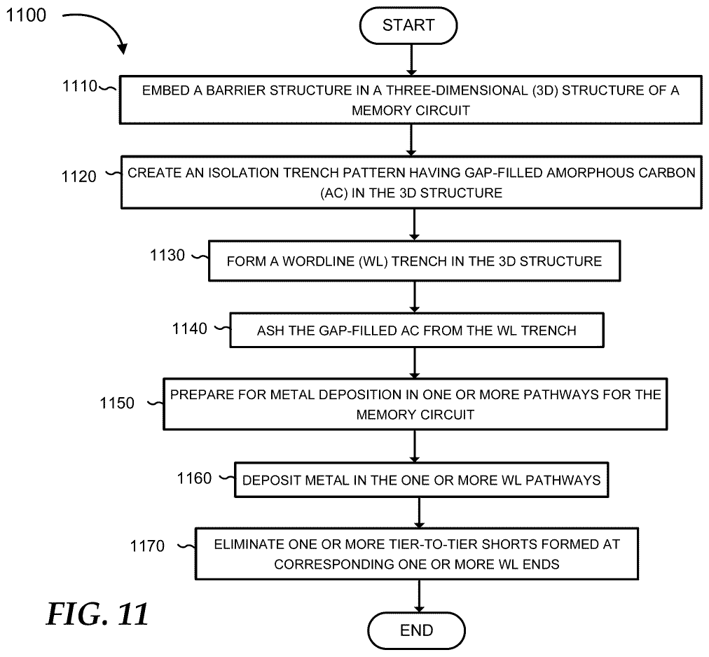

FIG. 11 is a flow chart illustrating a process 1100 of forming the barrier structure for a memory circuit according to an embodiment. The process 1100 may include more or less processes or steps than as shown in FIG. 11. In addition, processes or steps may not follow in the exact order as shown. Some processes or steps may take place at the same time.

The process 1100 embeds a barrier structure in a three-dimensional (3D) structure of a memory circuit (Process 1110). In some embodiments, the process 1110 corresponds to the process 520 shown in FIG. 6. In some embodiments, the process 1110 may also be performed in the CDTI process 510 shown in FIG. 5. The process 1110 may be performed by surrounding a barrier aC with a barrier liner. The term “barrier aC” refers to the aC used in the barrier structure. The barrier liner is configured to protect the barrier aC from being removed by the ashing of the gap-filled aC. In one embodiment, the barrier liner includes silicon nitride or any other nitride. The barrier liner corresponds to the liner 245 shown in FIG. 2.

Next, the process 1100 creates an isolation trench pattern having gap-filled amorphous carbon (aC) in the 3D structure (Process 1120). The process 1120 corresponds to the process 520 shown in FIG. 5 and the structure 650 shown in FIG. 6. The process 1120 and the process 1110 may take place at the same time. In other words, the barrier structure is formed while the ISO trench is created. Then, the process 1100 forms a WL trench in the 3D structure (Process 1130).

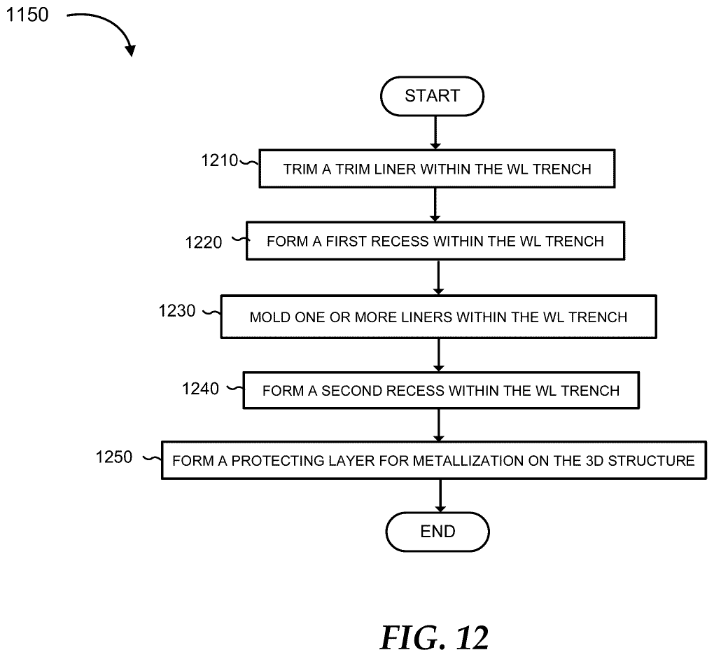

Next, the process 1100 ashes the gap-filled aC from the WL trench (Process 1140). The process 1140 corresponds to the structure 725 shown in FIG. 8. The ashing may be performed by a chemical oxidation or a plasma-based method. In some embodiments, oxygen plasma is used to ash the aC. The liner at the barrier structure acts as an etch stop and protects the barrier aC. Then, the process 1100 prepares for metal deposition in one or more pathways for the memory circuit (Process 1150). This preparation includes various processes or steps of etching, recessing, or molding to create circuit elements and interconnections. Thanks to the barrier structure that protects the WL pad area from a process effect which may include residues, fragments, reactants or agents, or any other foreign particles or impurities caused by one of a chemical, electrical, or mechanical reaction from a fabrication process such as etching, recessing, and molding. Without the process effect WLs may be formed in monolithic or one-body configurations that have no surface skewing at the boundary between the WL pad area and the cell array area. The process 1150 will be described further in FIG. 12.

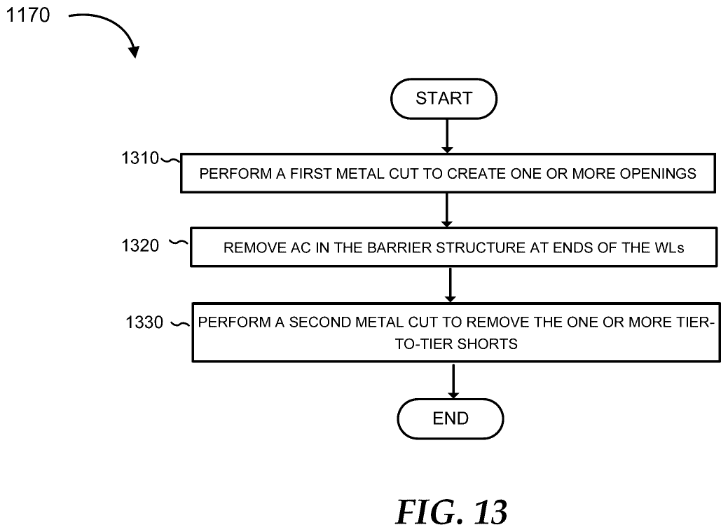

Then, the process 1100 deposits metal in the one or more WL pathways (Process 1160). The metal may be any suitable conductive material. In some embodiments, the metal may be any one of the following: tungsten (W), titanium nitride (TiN), molybdenum (Mo), aluminum (Al), copper (Cu), Cobalt (Co). ruthenium (Ru), iridium (Ir), platinum (Pt), tantalum (Ta), or rhodium (Rh). It may also be a combination of two or more of the above materials. Next, the process 1100 eliminates one or more tier-to-tier shorts formed at corresponding one or more WL ends (Process 1170). The process 1170 will be further described in FIG. 13. The process 1100 is then terminated.

FIG. 12 is a flow chart illustrating the process 1150 of preparing for metal deposition according to an embodiment. The process 1150 corresponds to parts of the process 530 shown in FIG. 7 and the structures shown in FIG. 8 and FIG. 9.

The process 1150 trims a trim liner within the WL trench (Process 1210). The process 1210 corresponds to the structure 735 shown in FIG. 8. Next, the process 1150 forms a first recess within the WL trench (Process 1220). The process 1230 corresponds to the structure 745 shown in FIG. 8. In some embodiments, the first recess is an oxide such as silicon oxide. Then, the process 1150 molding one or more liners within the WL trench (Process 1230). The process 1230 corresponds to the structure 755 shown in FIG. 9. In some embodiments, the one or more liners within the WL trench include at least one oxide liner or one nitride liner. In some embodiments, the one or more liners include one oxide liner, one nitride liner, and one oxide liner in a tri-liner configuration.

Next, the process 1150 forms a second recess within the WL trench (Process 1240). In some embodiments, the second recess is a nitride. Then, the process 1150 forms a protecting layer for metallization on the 3D structure (Process 1250). In some embodiments, the protecting layer is a gate oxide layer. The process 1150 is then terminated.

FIG. 13 is a flow chart illustrating the process 1170 of eliminating tier-to-tier shorts according to an embodiment. The process 1170 corresponds to the process 790 shown in FIG. 10.

The process 1170 performs a first metal cut to create one or more openings (Process 1310). The process 1310 corresponds to the structures 1060 and 1070 shown in FIG. 10. Next, the process 1170 removes or exhumes aC in the barrier structure at ends of the WLs (Process 1320). This may be performed by a chemical oxidation or a plasma-based method. In some embodiments, oxygen plasma is used to ash the aC. Then, the process 1170 performs a second metal cut to remove the one or more tier-to-tier shorts (Process 1330). This results in independent WLs that are free of shorting or connecting to each other. The process 1330 corresponds to structure 795 shown in FIG. 10. The process 1310 is then terminated.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A device comprising:
a barrier structure including a barrier liner surrounding a material configured to protect a wordline (WL) area from a process effect;
a first strip extending longitudinally in a first direction and separated into a first segment and a second segment by a space; and
a second strip extending longitudinally in a second direction and intersecting the second segment,
wherein the barrier structure extends longitudinally in the second direction between the first segment and the second segment in the space, and
wherein the barrier structure is positioned between the WL area and one of a WL dummy area or a cell array area of a memory circuit.

2. The device of claim 1, wherein the barrier liner is a silicon nitride liner.

3. The device of claim 1, wherein the material is amorphous carbon (aC).

4. The device of claim 1, wherein the first strip is aligned with a WL trench.

5. The device of claim 1, wherein the second strip is aligned with a deep trench isolation (DTI) trench.

6. The device of claim 1, wherein the first direction is substantially perpendicular to the second direction.

7. The device of claim 1, wherein the WL area is a WL pad area.

8. The device of claim 1, wherein the process effect includes a fabrication effect from at least one of etching, recessing, or molding.

9. The device of claim 1, wherein the barrier structure is positioned at a first distance from end of the first segment and a second distance from end of the second segment.

10. The device of claim 1, wherein a ratio between a width W₁ of the barrier and a length L of the barrier structure is less than a predetermined value.

11. A method comprising:
embedding a barrier structure in a three-dimensional (3D) structure of a memory circuit;
creating an isolation trench pattern having gap-filled amorphous carbon (aC) in the 3D structure;
forming a wordline (WL) trench in the 3D structure;
ashing the gap-filled aC from the WL trench;
depositing metal in one or more WL pathways; and
eliminating one or more tier-to-tier shorts formed at corresponding one or more WL ends.

12. The method of claim 11, wherein embedding the barrier structure comprises:
surrounding a barrier aC with a barrier liner, the barrier liner protecting the barrier aC from being removed by the ashing of the gap-filled aC.

13. The method of claim 11, further preparing for metal deposition, which comprises:
trimming a trim liner within the WL trench;
forming a first recess within the WL trench;
molding one or more liners within the WL trench;
forming a second recess within the WL trench; and
forming a protecting layer for metallization on the 3D structure.

14. The method of claim 12, wherein eliminating tier-to-tier shorts comprises:
performing a first metal cut to create one or more openings;
removing aC in the barrier structure at ends of the WLs; and
performing a second metal cut to remove the one or more tier-to-tier shorts.

15. The method of claim 14, wherein performing the second metal cut comprises:
flowing an etchant gas through the one or more openings, the etchant gas removing metal at the one or more tier-to-tier shorts.

16. The method of claim 12, wherein the barrier liner is a silicon nitride liner.

17. The method of claim 13, wherein the first recess is an oxide and the second recess is a nitride.

18. The method of claim 13, wherein the one or more liners within the WL trench include at least one oxide liner or one nitride liner.

19. The method of claim 13, wherein the protecting layer is a gate oxide layer.

20. A system comprising:
a memory circuit comprising:
a wordline (WL) area and at least one of a WL dummy area or a cell array area; and
a barrier region comprising:
a barrier structure including a protecting liner surrounding a material configured to protect the WL area from a process effect;
a first strip extending longitudinally in a first direction and separated into a first segment and a second segment by a space; and
a second strip extending longitudinally in a second direction and intersecting the second segment,
wherein the barrier structure extends longitudinally in the second direction between the first segment and the second segment in the space, and
wherein the barrier structure is positioned between the WL area and at least one of the WL dummy area or the cell array area.
